(19) United States
(12) Patent Application Publication
(10) Pub. No.: US 2026/0157089 A1
(43) Pub. Date: Jun. 4, 2026

(54) DISPLAY SUBSTRATE AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Bingwei Yang, Beijing (CN); Hao Gao, Beijing (CN); Shun Wang, Beijing (CN)

(21) Appl. No.: 18/704,006

(22) PCT Filed: Apr. 24, 2023
(86) PCT No.: PCT/CN2023/090333

§ 371 Date: Apr. 23, 2024

(51) Int. Cl. H10K 59/80; H10K 50/19; H10K 102/00

(52) U.S. Cl. CPC H10K 59/879; H10K 59/80524; H10K 59/873; H10K 50/19; H10K 2102/3026

(57) ABSTRACT

A display substrate is provided, including: a base substrate; and a first electrode, a first light-emitting layer, a first hole blocking layer, a first electron transport layer, an electron injection layer, a second electrode, an optical extraction layer, a protective layer and an encapsulation layer sequentially arranged in a direction away from the base substrate. A refractive index of a material of the optical extraction layer is greater than that of a material of the protective layer, and the refractive index of the material of the protective layer is greater than that of a material of the second electrode.

### CROSS-REFERENCE TO RELATED APPLICATION

This application is a Section 371 National Stage Application of International Application No. PCT/CN2023/090333, filed Apr. 24, 2023, entitled “DISPLAY SUBSTRATE AND DISPLAY DEVICE”, which is incorporated herein by reference in its entirety.

### TECHNICAL FIELD

The present disclosure relates to the field of display technology, in particular to a display substrate and a display device.

### BACKGROUND

Organic light-emitting diode (OLED) devices have attracted much attention due to their advantages of self-luminescence, rich color, fast response speed, wide viewing angle, light weight, thin thickness, low power consumption, and the ability to achieve flexible display. In related art, the greater the fluctuation in thicknesses of film layers in OLED, the greater the impact on the uniformity of screen displays, and there is generally a color shift problem in OLED.

The above information disclosed in this section is only for the understanding of the background of the technical concept of the present disclosure. Therefore, the above information may include information that does not constitute the prior art.

### SUMMARY

To solve at least one aspect of the aforementioned problem, embodiments of the present disclosure provide a display substrate and a display device including the display substrate.

At one aspect, a display substrate is provided, including: a base substrate; a first electrode on the base substrate; a first light-emitting layer on a side of the first electrode away from the base substrate; a first hole blocking layer on a side of the first light-emitting layer away from the base substrate; a first electron transport layer on a side of the first hole blocking layer away from the base substrate; an electron injection layer on a side of the first electron transport layer away from the base substrate; a second electrode on a side of the electron injection layer away from the base substrate; an optical extraction layer on a side of the second electrode away from the base substrate; a protective layer on a side of the optical extraction layer away from the base substrate; and an encapsulation layer on a side of the protective layer away from the base substrate, wherein a refractive index of a material of the optical extraction layer is greater than a refractive index of a material of the protective layer, and the refractive index of the material of the protective layer is greater than a refractive index of a material of the second electrode.

According to some exemplary embodiments, the display substrate includes a color shift adjustment layer, the color shift adjustment layer is selected from at least one of the optical extraction layer, the protective layer, or the encapsulation layer, and the color shift adjustment layer and the second electrode meet:

$$\sum ( {n}_{i} {L}_{i} ) / \sum {L}_{i} = K ,$$

wherein n represents a refractive index of a material of each layer, L represents a thickness of each layer, i is a positive integer, and K is greater than 1.

According to some exemplary embodiments, the encapsulation layer includes: a first inorganic layer on the side of the protective layer away from the base substrate; a second insertion layer on a side of the first inorganic layer away from the base substrate; an organic layer on a side of the second insertion layer away from the base substrate; and a second inorganic layer on a side of the organic layer away from the base substrate.

According to some exemplary embodiments, the refractive index n₁ of the material of the second electrode, a thickness L₁ of the second electrode, a refractive index n₂ of a material of the second insertion layer and a thickness L₂ of the second insertion layer meet:

$$( {n}_{1} {L}_{1} + {n}_{2} {L}_{2} ) / ( {L}_{1} + {L}_{2} ) = K ,$$

wherein K is in a range of 1.3 to 1.6.

According to some exemplary embodiments, the refractive index n₁ of the material of the second electrode and the refractive index n₂ of the material of the second insertion layer meets |n₁−n₂|>1.

According to some exemplary embodiments, the encapsulation layer includes: a first insertion layer on the side of the protective layer away from the base substrate; a first inorganic layer on a side of the first insertion layer away from the base substrate; an organic layer on a side of the first inorganic layer away from the base substrate; and a second inorganic layer on a side of the organic layer away from the base substrate.

According to some exemplary embodiments, the refractive index n₁ of the material of the second electrode, a thickness L₁ of the second electrode, the refractive index n₃ of the material of the optical extraction layer, a thickness L₃ of the optical extraction layer, the refractive index n₄ of the material of the protective layer, a thickness L₄ of the protective layer, a refractive index n₅ of a material of the first insertion layer and a thickness L₅ of the first insertion layer meet:

$$( {n}_{1} {L}_{1} + {n}_{3} {L}_{3} + {n}_{4} {L}_{4} + {n}_{5} {L}_{5} ) / ( {L}_{1} + {L}_{3} + {L}_{4} + {L}_{5} ) = K ,$$

wherein K is in a range of 1.5 to 2.0.

According to some exemplary embodiments, the refractive index n₁ of the material of the second electrode and the refractive index n₃ of the material of the optical extraction layer meets |n₁−n₃|>1.

According to some exemplary embodiments, the refractive index n₄ of the material of the protective layer and the refractive index n₃ of the material of the optical extraction layer meets |n₄−n₃|>0.3.

According to some exemplary embodiments, the refractive index n₅ of the material of the first insertion layer and the refractive index n₄ of the material of the protective layer meets |n₅−n₄|>0.2.

According to some exemplary embodiments, the encapsulation layer includes: a first inorganic layer on the side of the protective layer away from the base substrate; an organic layer on a side of the first inorganic layer away from the base substrate; and a second inorganic layer on a side of the organic layer away from the base substrate.

According to some exemplary embodiments, a refractive index n₁ of the material of the second electrode, a thickness L₁ of the second electrode, a refractive index n₃ of the material of the optical extraction layer, a thickness L₃ of the optical extraction layer, a refractive index n₄ of the material of the protective layer and a thickness L₄ of the protective layer meet:

$$( {n}_{1} {L}_{1} + {n}_{3} {L}_{3} + {n}_{4} {L}_{4} ) / ( {L}_{1} + {L}_{3} + {L}_{4} ) = K ,$$

wherein K is 1.5.

According to some exemplary embodiments, a product n₃·L₃ of a refractive index n₃ of the material of the optical extraction layer and a thickness L₃ of the optical extraction layer is in a range of 90 to 120.

According to some exemplary embodiments, a refractive index n₃ of the material of the optical extraction layer meets n₃>1.7.

According to some exemplary embodiments, a product n₂·L₂ of a refractive index n₂ of a material of the second insertion layer and a thickness L₂ of the second insertion layer is in a range of 130 to 190.

According to some exemplary embodiments, the refractive index n₂ of the material of the second insertion layer meets 1.5<n₂<1.8.

According to some exemplary embodiments, a product n₄·L₄ of a refractive index n₄ of the material of the protective layer and a thickness La of the protective layer is in a range of 56 to 84.

According to some exemplary embodiments, the refractive index n₄ of the material of the protective layer meets 1.4<n₄<1.5.

According to some exemplary embodiments, a product n₁·L₁ of a refractive index n₁ of the material of the second electrode and a thickness L₁ of the second electrode is in a range of 1.28 to 1.92.

According to some exemplary embodiments, the above-mentioned display substrate may further include: a hole injection layer on the side of the first electrode away from the base substrate; a first hole transport layer on a side of the hole injection layer away from the base substrate; a second light-emitting layer on a side of the first hole transport layer away from the base substrate; a second hole blocking layer on a side of the second light-emitting layer away from the base substrate; a second electron transport layer on a side of the second hole blocking layer away from the base substrate; a charge generation layer on a side of the second electron transport layer away from the base substrate; and a second hole transport layer on a side of the charge generation layer away from the base substrate, wherein the first light-emitting layer is on a side of the second hole transport layer away from the base substrate.

According to some exemplary embodiments, a material of the first electrode includes at least one of silver, indium tin oxide/silver/indium tin oxide, or a nickel chromium alloy; the material of the second electrode includes at least one of a transparent conductive oxide, a magnesium silver alloy, aluminum, magnesium, or silver.

According to some exemplary embodiments, Sdrop≤0, and Sdrop is obtained through a following equation:

$$Sdrop = ( ( Ssplit - Sref . ) / Sref . ) * 100 \% ,$$

wherein Ssplit is an area of an enclosed color gamut of the display substrate in a color space, Sref. is an area of an enclosed color gamut of a reference display substrate in the color space, and Sdrop is a variation of split S with respect to Sref.

On another aspect, a display device is further provided, including the above-mentioned display substrate.

### BRIEF DESCRIPTION OF THE DRAWINGS

Through the following descriptions of the present disclosure with reference to the accompanying drawings, the other objectives and advantages of the present disclosure will be apparent and may help to have a comprehensive understanding of the present disclosure.

FIG. 1A is a schematic diagram of a display substrate according to an embodiment of the present disclosure;

FIG. 1B is a schematic diagram of a stack of a display substrate according to an embodiment of the present disclosure;

FIG. 1C is a schematic diagram of a display substrate including a plurality of first light-emitting layers according to an embodiment of the present disclosure;

FIG. 2 is a schematic diagram of an encapsulation layer according to an embodiment of the present disclosure;

FIG. 3A is a schematic diagram showing reduction of color shift difference in a case of the encapsulation layer shown in FIG. 2 according to an embodiment of the present disclosure;

FIG. 3B shows a relationship between an amount of color shift difference and a size of a display substrate according to an embodiment of the present disclosure;

FIG. 4 is a schematic diagram of an encapsulation layer according to another embodiment of the present disclosure;

FIG. 5 is a schematic diagram showing reduction of color shift difference in a case of the encapsulation layer shown in FIG. 4 according to an embodiment of the present disclosure;

FIG. 6 is a schematic diagram of an encapsulation layer according to another embodiment of the present disclosure;

FIG. 7A is a schematic diagram showing reduction of color shift difference in a case of the encapsulation layer shown in FIG. 6 according to an embodiment of the present disclosure;

FIG. 7B is diagram showing a relationship between an effective thickness and an amount of color shift difference in a case of the encapsulation layer shown in FIG. 6 according to an embodiment of the present disclosure;

FIG. 8A is a schematic diagram showing reduction of color shift difference in a case of only adjusting a second insertion layer according to an embodiment of the present disclosure;

FIG. 8B is a diagram showing a relationship between an effective thickness and an amount of color shift difference in a case of only adjusting a second insertion layer according to an embodiment of the present disclosure;

FIG. 9A is a schematic diagram showing reduction of color shift difference in a case of only adjusting a protective layer according to an embodiment of the present disclosure; and

FIG. 9B is a diagram showing a relationship between an effective thickness and an amount of color shift difference in a case of only adjusting a protective layer according to an embodiment of the present disclosure.

It will be noted that for clarity, dimensions of layers, structures or regions may be enlarged or reduced in the drawings used to describe the embodiments of the present disclosure. That is, these drawings are not drawn to actual scales.

### DETAILED DESCRIPTION OF EMBODIMENTS

Hereinafter, further specific explanations of the technical solutions of the present disclosure will be provided through embodiments in conjunction with the accompanying drawings. In the specification, the same or similar reference numerals indicate the same or similar components. The following explanation of the embodiments of the present disclosure with reference to the accompanying drawings is intended to explain the overall inventive concept of the present disclosure and should not be understood as a limitation on the present disclosure.

In addition, in the following detailed description, for ease of explanation, many specific details are elaborated to provide a comprehensive understanding of the embodiments of the present disclosure. However, it is obvious that one or more embodiments may also be implemented without these specific details.

It will be understood that, although the terms “first”, “second”, etc. may be used here to describe different elements, these elements should not be limited by these terms. These terms are only used to distinguish one element from another. For example, without departing from the scope of exemplary embodiments, the first element may be named as the second element, and similarly, the second element may be named as the first element. The term “and/or” used here includes any combination and all combinations of one or more related listed items.

In will be understood that, when an element or a layer is referred to as “formed on” a further element or layer, the element or layer may be directly or indirectly formed on the further element or layer. That is to say, for example, there may be an intermediate element or an intermediate layer. On the contrary, when an element or a layer is referred to as “directly formed on” a further element or layer, there is no intermediate element or intermediate layer. Other expressions used to describe a relationship between elements or layers will be explained in a similar way (such as “between” and “directly between”, “adjacent” and “directly adjacent”, etc.).

Herein, unless otherwise specified, the expression “in the same layer” generally means that the first and second components may be formed using a same material and through a same patterning process. The expression “A and B are connected as an integral structure” indicates that the component A and the component B are formed as an integral structure, that is, they usually include a same material and are formed as a continuous component as a whole in structure.

Herein, unless otherwise specified, oriental terms such as “up”, “down”, “left”, “right”, “inside”, “outside” are used to represent an orientation or a positional relationship based on the drawings, and they are only for ease of description of the present disclosure, but are not to indicate or imply that the device, element or component referred has to have a specific orientation, or be constructed or operated in a specific orientation. It will be understood that when an absolute position of a described object changes, a relative positional relationship they represent may also change accordingly. Therefore, these directional terms should not be understood as a limitation on the present disclosure.

Herein, the expression “vertical”, “vertical connection” or similar expressions not only include a case of 90 degrees, namely a case of being completely vertical, but also include a case of a deviation from 90 degrees within a certain error range, for example, a case of a deviation from 90 degrees within a fabrication error range.

Those skilled in the art will understand that herein, unless otherwise specified, the expression “height” or “thickness” refers to a dimension along a surface of each film layer provided perpendicular to the display substrate, that is, a dimension along a light output direction of the display substrate, or a dimension along a normal direction of the display device.

Herein, oriental expressions such as “first direction” and “second direction” are used to describe different directions along pixel units, such as vertical and horizontal directions of pixel units, or row and column directions of sub-pixel arrangements. It will be understood that these representations are only illustrative, but not limitations on the present disclosure.

OLED organic materials are generally prepared through vapor deposition, and an accuracy of a preparation process affects the film thickness uniformity. The greater a fluctuation of a film thickness, the greater the impact on the uniformity of the screen display. That is, for color shift at different points, the greater the fluctuation of the film thickness, the larger an area distributed with scattered points (margin) at a fixed angle. The color shift difference is more pronounced on display screens of laptops or display screens of car terminals. For example, on these types of display screen, when performing 9 point display or 135 point display, differences between points are particularly significant. To reduce the color shift difference, due to hardware limitations of the device, it is difficult to achieve significant reduction of the color shift difference by only improving the process performance of the equipment.

In view of this, the embodiments of the present disclosure provide a plurality of embodiments of OLED structures to effectively reduce the color shift difference. Specifically, since pixels in the OLED panel are mostly R (Red), G (Green) and B (Blue) sub-pixel structures, a color shift change of white light changes with R, G and B changes. Color shift difference may be reduced by providing an OLED with different structures, and a principle involved is that color shift at white light angles may be adjusted by adjusting an extent of influence of RGB on the color shift of the white light, i.e. a sensitivity of monochrome, so as to reduce color shift differences between different points of the product.

Specifically, an embodiment of the present disclosure provides a display substrate, including: a base substrate; a first electrode on the base substrate; a first light-emitting layer on a side of the first electrode away from the base substrate; a first hole blocking layer on a side of the first light-emitting layer away from the base substrate; a first electron transport layer on a side of the first hole blocking layer away from the base substrate; an electron injection layer on a side of the first electron transport layer away from the base substrate; a second electrode on a side of the electron injection layer away from the base substrate; an optical extraction layer on a side of the second electrode away from the base substrate; a protective layer on a side of the optical extraction layer away from the base substrate; and an encapsulation layer on a side of the protective layer away from the base substrate. A refractive index of a material of the optical extraction layer is greater than a refractive index of a material of the protective layer, and the refractive index of the material of the protective layer is greater than a refractive index of a material of the second electrode.

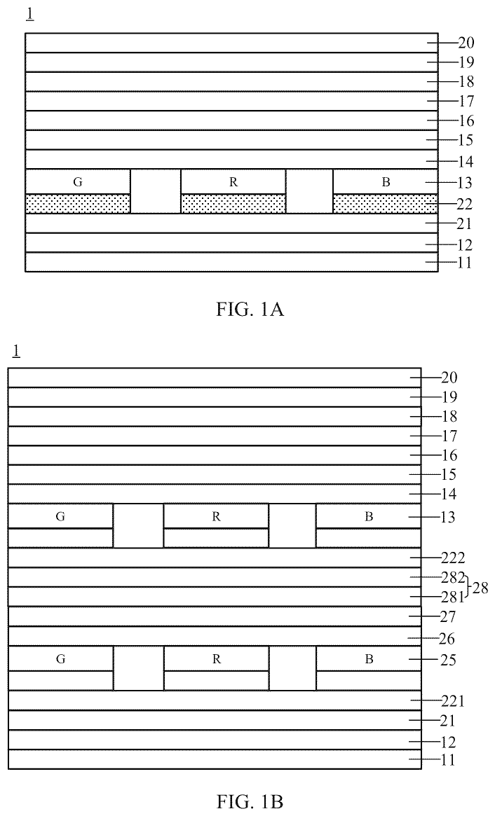

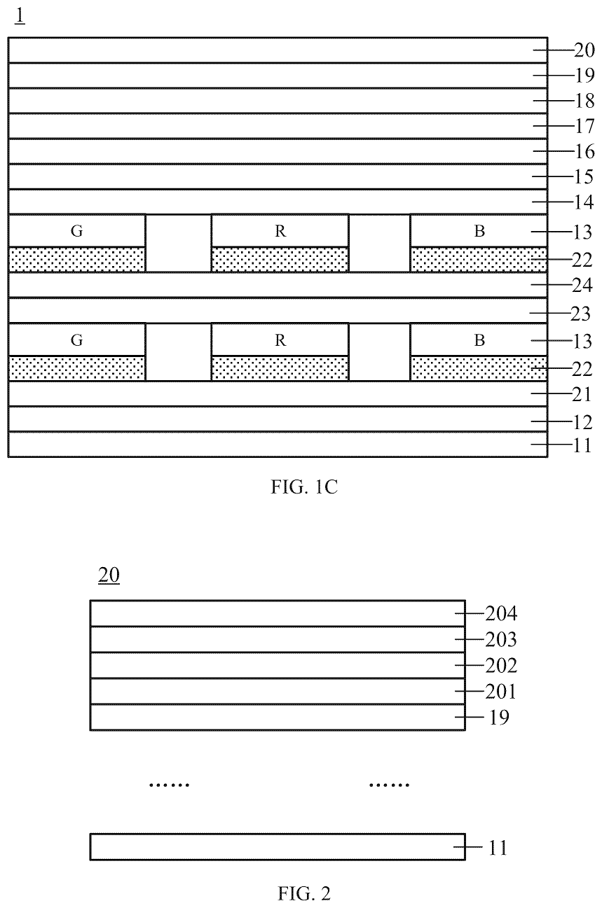

FIG. 1A is a schematic diagram of a display substrate according to an embodiment of the present disclosure.

As shown in FIG. 1A, a display substrate 1 may include: a base substrate 11; a first electrode 12 on the base substrate 11; a first light-emitting layer 13 on a side of the first electrode 12 away from the base substrate 11; a first hole blocking layer 14 on a side of the first light-emitting layer 13 away from the base substrate 11; a first electron transport layer 15 on a side of the first hole blocking layer 14 away from the base substrate 11; an electron injection layer 16 on a side of the first electron transport layer 15 away from the base substrate 11; a second electrode 17 on a side of the electron injection layer 16 away from the base substrate 11; an optical extraction layer 18 on a side of the second electrode 17 away from the base substrate 11; a protective layer 19 on a side of the optical extraction layer 18 away from the base substrate 11; and an encapsulation layer 20 on a side of the protective layer 19 away from the base substrate. A refractive index of a material of the optical extraction layer 18 is greater than a refractive index of a material of the protective layer 19, and the refractive index of the material of the protective layer 19 is greater than a refractive index of a material of the second electrode 17.

According to an embodiment of the present disclosure, the first electrode 12 may serve as an anode, and the second electrode 17 may serve as a cathode. The display substrate provided in the embodiments of the present disclosure may be a top emission device. Therefore, anode and cathode materials of the top emission OLED device in the prior art may be used, and the anode and cathode materials in the embodiments of the present disclosure may be adjusted according to actual needs. For example, a material of the first electrode may include at least one of silver (Ag), indium tin oxide/silver/indium tin oxide (ITO/Ag/ITO), or a nickel chromium alloy (Ni: Cr alloy). A material of the second electrode 17 may be at least one selected from a transparent conductive oxide, a magnesium silver alloy, aluminum, magnesium, or silver, for example, ITO and other transparent conductive oxides, and Mg/Ag/Al/or alloys may be preferred.

According to an embodiment of the present disclosure, the first light-emitting layer 13 may include structures of R, G, and B sub-pixels, where the R sub-pixel may serve as a first sub light-emitting layer, the G sub-pixel may serve as a second sub light-emitting layer, and the B sub-pixel may serve as a third sub light-emitting layer.

According to an embodiment of the present disclosure, the color shift difference reduction solution in the present disclosure may be applied to top emission devices, as there may be a structure enhancing microcavity refraction in the top emission device, thereby reducing the color shift difference of the display substrate.

According to an embodiment of the present disclosure, the encapsulation layer may include at least one of a first insertion layer, a first inorganic layer, a second insertion layer, an organic layer or a second inorganic layer. The color shift difference of the display substrate may be reduced by performing color shift adjustment on one or more layers in the optical extraction layer 18, the protective layer 19, and the encapsulation layer 20.

According to an embodiment of the present disclosure, a hole injection layer 21, a hole transport layer 22, etc. may be provided between the first electrode 12 and the first light-emitting layer 13 as desired, which will not be repeated here.

FIG. 1B is a schematic diagram of a stack of a display substrate according to an embodiment of the present disclosure.

As shown in FIG. 1B, the display substrate 1 may further include: the hole injection layer 21 on the side of the first electrode 12 away from the base substrate 11; a first hole transport layer 221 on a side of the hole injection layer 21 away from the base substrate 11; a second light-emitting layer 25 on a side of the first hole transport layer 221 away from the base substrate 11; a second hole blocking layer 26 on a side of the second light-emitting layer 25 away from the base substrate 11; a second electron transport layer 27 on a side of the second hole blocking layer 26 away from the base substrate 11; a charge generation layer 28 on a side of the second electron transport layer 27 away from the base substrate 11; and a second hole transport layer 222 on a side of the charge generation layer 28 away from the base substrate 11, where the first light-emitting layer 13 is on a side of the second hole transport layer 222 away from the base substrate 11. The charge generation layer 28 may include an N-type charge generation layer 281 and a P-type charge generation layer 282. It will be understood that the color shift difference reduction solution provided in the embodiments of the present disclosure may also be applied to the stack device shown in FIG. 1B.

FIG. 1C is a schematic diagram of a display substrate including a plurality of first light-emitting layers according to an embodiment of the present disclosure.

The first light-emitting layer 13 in the display substrate 1 may be provided with one layer or a plurality of layers, as shown in FIG. 1C. The main difference between FIG. 1C and FIG. 1A is that two first light-emitting layers 13 are provided in FIG. 1C, as well as that an electron generation layer 23, a hole generation layer 24, a hole transport layer 22, etc. are provided between the two first light-emitting layers. Optionally, three first light-emitting layers sequentially stacked may be provided in the display substrate, and correspondingly, structures such as the electron generation layer, the hole generation layer and the hole transport layer may be provided between the light-emitting layers according to actual needs, which will not be repeated here. It will be understood that the color shift difference reduction solution provided in the embodiments of the present disclosure may be applied to a display substrate having a single light-emitting layer structure, or to a display substrate having a plurality of light-emitting layers that are stacked.

According to an embodiment of the present disclosure, one or more of the optical extraction layer 18, the protective layer 19 and the encapsulation layer 20 may serve as a color shift adjustment layer to reduce the color shift difference of the display substrate. The color shift adjustment layer and the second electrode 17 may have a relationship represented by equation (1):

$$\sum ( {n}_{i} {L}_{i} ) / \sum {L}_{i} = K . \qquad ( 1 )$$

Here, n may represent a refractive index of a material of each layer, L may represent a thickness of each layer, i is a positive integer, and K is greater than 1.

FIG. 2 is a schematic diagram of an encapsulation layer according to an embodiment of the present disclosure.

As shown in FIG. 2, the encapsulation layer 20 may include: a first inorganic layer 201 on the side of the protective layer 19 away from the base substrate 11; a second insertion layer 202 on a side of the first inorganic layer 201 away from the base substrate 11; an organic layer 203 on a side of the second insertion layer 202 away from the base substrate 11; and a second inorganic layer 204 on a side of the organic layer 203 away from the base substrate 11. The sign “ . . . ” in FIG. 2 may represent an omitted film layer structure between the base substrate 11 and the protective layer 19.

According to an embodiment of the present disclosure, in the case where the encapsulation layer 20 includes the first inorganic layer 201, the second insertion layer 202, the organic layer 203 and the second inorganic layer 204, the second electrode 17 and the second insertion layer 202 may serve as the color shift adjustment layer to reduce the color shift difference of the display substrate. Specifically, a refractive index n₁ of a material of the second electrode 17, a thickness L₁ of the second electrode 17, a refractive index n₂ of a material of the second insertion layer 202 and a thickness L₂ of the second insertion layer 202 may have a relationship represented by equation (2):

$$( {n}_{1} {L}_{1} + {n}_{2} {L}_{2} ) / ( {L}_{1} + {L}_{2} ) = K . \qquad ( 2 )$$

Here, K may be in a range of 1.3 to 1.6, and the refractive index n₁ of the material of the second electrode 17 and the refractive index n₂ of the material of the second insertion layer 202 may meet |n₁−n₂|>1.

The material of the second insertion layer 202 may be organic or inorganic film layers, such as SiN or SiON. Preferably, the refractive index n₁ of the material of the second electrode 17 may be in a range of 0.14 to 0.18, the refractive index n₂ of the material of the second insertion layer 202 may be in a range of 1.5 to 1.8, the thickness L₁ of the second electrode 17 may be in a range of 8 nm to 12 nm, and the thickness L₂ of the second insertion layer 202 may be in a range of 80 nm to 100 nm.

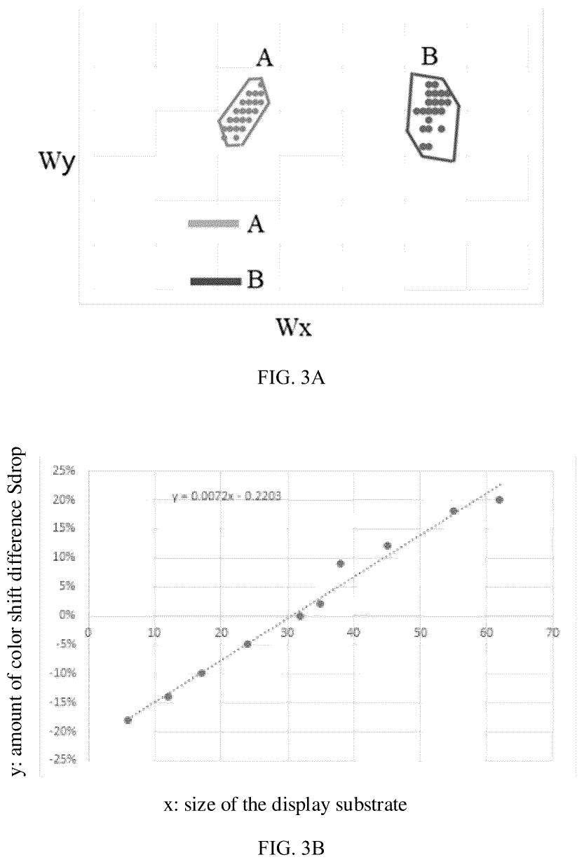

FIG. 3A is a schematic diagram showing reduction of color shift difference in a case of the encapsulation layer shown in FIG. 2 according to an embodiment of the present disclosure.

As shown in FIG. 3A, horizontal coordinates and vertical coordinates respectively represent horizontal coordinates and vertical coordinates in the color space. In a two-dimensional space, color coordinates of a pixel may be determined through a horizontal coordinate and a vertical coordinate. In FIG. 3A, the points in box A represent measured data of pixels in the display substrate at a same viewing angle. The border of box A is a boundary fitted for matching of experimental results, and pixels in box A may be orange pixels. Box B may serve as reference data for domain box A under the same experimental conditions. The smaller an area of box A, the smaller the color difference, indicating that the color shift difference may be reduced. To determine the extent of the color shift difference reduction, the area of box A and an area of box B may be substituted into equation (3) to obtain a reduction result:

$$Sdrop = ( ( Ssplit - Sref . ) / Sref . ) * 100 \% . \qquad ( 3 )$$

Here, Ssplit represents an area of an enclosed color gamut of the display substrate in the color space, and Ssplit may be understood as the area of box A. Sref. represents an area of an enclosed color gamut of a reference display substrate in the color space, and Sref. may be understood as the area of box B. Sdrop may be understood as a variation of Ssplit with respect to Sref. Ref. Sdrop=0% is a minimum standard, and Sdrop being a negative value indicates the color shift difference is reduced. In the above embodiments, a result of the color shift difference reduction obtained may be as follows: the color shift is 5.6 JNCD (Just Noticeable Color Difference, a measurement criterion of screen color accuracy), and the color shift difference is reduced by 47.8% with respect to the reference data.

According to an embodiment of the present disclosure, in FIG. 3A, a coverage area of CIE1931 (a mathematically defined color space) color gamut may reach up to 101% NTSC (a color standard). As the thickness of the second electrode 17 changes, the color shift of R, G and B may be simultaneously strengthened or weakened as the angle changes, resulting in a significant change in the margin of the color shift of the synthesized white light. Also, the low refractive index of the second insertion layer 202 may adjust the color shift difference of red light at a large angle and change a sensitivity of the impact of the red light on the white light, thereby affecting a lateral distribution of the scattered points.

In the case where the second electrode 17 and the second insertion layer 202 may serve as the color shift adjustment layer, a peak position in a spectrum of the first sub light-emitting layer may be in a range of 620 nm to 640 nm, a peak position in a spectrum of the second sub light-emitting layer may be in a range of 515 nm to 535 nm, and a peak position in a spectrum of the third sub light-emitting layer may be in a range of 445 nm to 465 nm. The influence of the thickness of the second electrode on the RGB spectrums of each light-emitting layer may be represented by equations (4) to (6).

In a case that the thickness L₁ of the second electrode 17 is in a range of 8 nm to 16 nm, the following equations are met:

$$R\_Peak wave = 1.04 ( {L}_{1} ) + 614 \qquad ( 4 )$$

$$G\_Peak wave = 0.67 {L}_{1} + 513 \qquad ( 5 )$$

$$B\_Peak wave = 458 ( {L}_{1} = 8 ∼ 11 nm ) or 459 ( {L}_{1} = 12 \sim 16 nm ) \qquad ( 6 )$$

Here, R_Peak wave may represent a peak position of the red light in the spectrum, G_Peak wave may represent a peak position of the green light in the spectrum, and B_Peak wave may represent a peak position of the blue light in the spectrum.

According to an embodiment of the present disclosure, the film layer structure between the first hole blocking layer 14 and the encapsulation layer 20 may form a microcavity. By matching the relationship between the thickness of the color shift adjustment layer with the refractive index and then defining the relationship, it is possible to adjust the microcavity effect, so as to reduce the area of the Ssplit (which may be understood as the area of box A in FIG. 3A), thereby reducing the color shift difference of the display substrate.

FIG. 3B shows a relationship between an amount of color shift difference and a size of a display substrate according to an embodiment of the present disclosure.

As shown in FIG. 3B, the horizontal coordinate may represent the size of the display substrate, and the vertical coordinate may represent the amount of color shift difference (Sdrop). There is also certain differences in Sdrop relationships corresponding to products with different sizes (inch, In). Under the same microcavity device and the same structural change conditions, experimental results of products with different sizes show that there is an approximate linear relationship between Sdrop and In (the size being above 6 inches) as shown in FIG. 3B. This approximate linear relationship may be represented by equation (7).

$$Sdrop = - 0.0051 \times I n - 0.0713 \qquad ( 7 )$$

Here, Sdrop represents the amount of color shift difference, and In represents the size of the display substrate. Equation (7) may be applicable to situations such as film layers in the microcavity being increased or decreased, a stack structure, a multi-layer encapsulation structure, COE (color filter on encapsulation, which is formed by depositing a layer of color filters after encapsulating AMOLED (active matrix organic light-emitting diode), EES (electrochemical and energy storage) devices, and materials of film layers having differences.

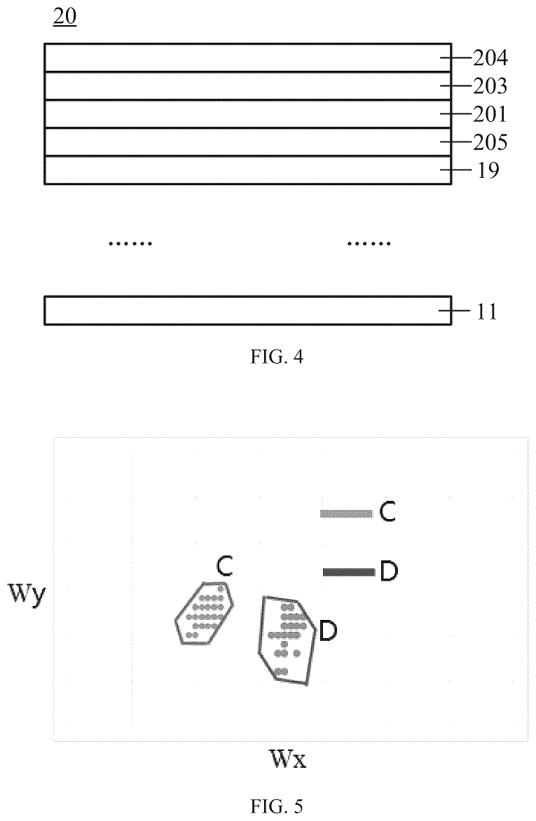

FIG. 4 is a schematic diagram of an encapsulation layer according to another embodiment of the present disclosure.

As shown in FIG. 4, the encapsulation layer 20 may include: a first insertion layer 205 on the side of the protective layer 19 away from the base substrate 11; the first inorganic layer 201 on a side of the first insertion layer 205 away from the base substrate 11; the organic layer 203 on a side of the first inorganic layer 201 away from the base substrate 11; and the second inorganic layer 204 on a side of the organic layer 203 away from the base substrate 11. The sign “ . . . ” in FIG. 4 may represent an omitted film layer structure between the base substrate 11 and the protective layer 19.

According to an embodiment of the present disclosure, in the case where the encapsulation layer 20 includes the first insertion layer 205, the first inorganic layer 201, the organic layer 203 and the second inorganic layer 204, the second electrode 17, the optical extraction layer 18, the protective layer 19 and the first insertion layer 205 may serve as the color shift adjustment layer to reduce the color shift difference of the display substrate. Specifically, the refractive index n₁ of the material of the second electrode 17, the thickness L₁ of the second electrode 17, a refractive index n₃ of the material of the optical extraction layer 18, a thickness L₃ of the optical extraction layer 18, a refractive index n₄ of a material of the protective layer 19, a thickness La of the protective layer 19, a refractive index n₅ of a material of the first insertion layer 205 and a thickness L₅ of the first insertion layer 205 may have a relationship represented by equation (8):

$$( {n}_{1} {L}_{1} + {n}_{3} {L}_{3} + {n}_{4} {L}_{4} + {n}_{5} {L}_{5} ) / ( {L}_{1} + {L}_{3} + {L}_{4} + {L}_{5} ) = K \qquad ( 8 )$$

Here, K is in a range of 1.5 to 2.0; the refractive index mi of the material of the second electrode 17 and the refractive index n₃ of the material of the optical extraction layer 18 may meet |n₁−n₃|>1; the refractive index n₄ of the material of the protective layer 19 and the refractive index n₃ of the material of the optical extraction layer 18 may meet |n₄−n₃|>0.3; a relationship between the refractive index n₅ of the material of the first insertion layer 205 and the refractive index n₄ of the material of the protective layer 19 may meet |n₅−n₄|>0.2.

According to an embodiment of the present disclosure, the material of the optical extraction layer 18 may be an organic material, and the material of the first insertion layer 205 may be an inorganic film layer such as SiN and SiON. As an organic layer, the optical extraction layer 18 may have a refractive index greater than 1.8. A refractive index of a short wavelength is greater than that of a long wavelength, so that a sensitivity of the optical extraction layer 18 to the blue light is relatively high. A refractive index of an auxiliary light layer is generally set to be less than 1.5, so as to achieve a significant color shift difference adjustment effect at large angles.

FIG. 5 is a schematic diagram showing reduction of color shift in a case of the encapsulation layer shown in FIG. 4 according to an embodiment of the present disclosure.

As shown in FIG. 5, the maximum color gamut coverage of CIE1931 is 99.2% of NTSC. The points in box C represent measured data of pixels in the display substrate at a same viewing angle. The border of box C is a boundary fitted for matching of experimental results, and pixels in box C may be green pixels. Box D may serve as reference data for domain box C under the same experimental conditions. The smaller an area of box C, the smaller the color difference, indicating that the color shift difference may be reduced. To determine the extent of the color shift difference reduction, the area of box C which may be used as Ssplit and the area of box D which may be used Sref. may be substituted into equation (3) to obtain a result of the color shift difference reduction Sdrop. In this embodiment, K is 1.52, and the Sdrop obtained is −25%.

In this embodiment, the peak position in the spectrum of the first sub light-emitting layer may be in a range of 615 nm to 635 nm, the peak position in the spectrum of the second sub light-emitting layer may be in a range of 510 nm to 530 nm, and the peak position in the spectrum of the third sub light-emitting layer may be in a range of 450 nm to 465 nm. The influence of the thickness of the second electrode on the RGB spectrums of each light-emitting layer may be represented by equations (9) to (11).

In a case that the thickness L₁ of the second electrode 17 is in a range of 8 nm to 16 nm, the following equations are met:

$$R\_Peak wave = 0.36 ( {L}_{1} ) + 626 \qquad ( 9 )$$

$$G\_Peak wave = 547 ( 8 - 12 nm ) \& 546 ( 13 - 16 nm ) \qquad ( 10 )$$

$$B\_Peak wave = 458 ( 8 - 12 nm ) \& 459 ( 13 - 16 nm ) \qquad ( 11 )$$

Here, R_Peak wave may represent the peak position of the red light spectrum, G_Peak wave may represent the peak position of the green light spectrum, and B_Peak wave may represent the peak position of the blue light spectrum.

According to the embodiments of the present disclosure, the area (which may be understood as the area of box C in FIG. 5) of the Ssplit may be reduced by adjusting the thickness and refractive index of each film layer, thereby reducing the color shift difference of the display substrate.

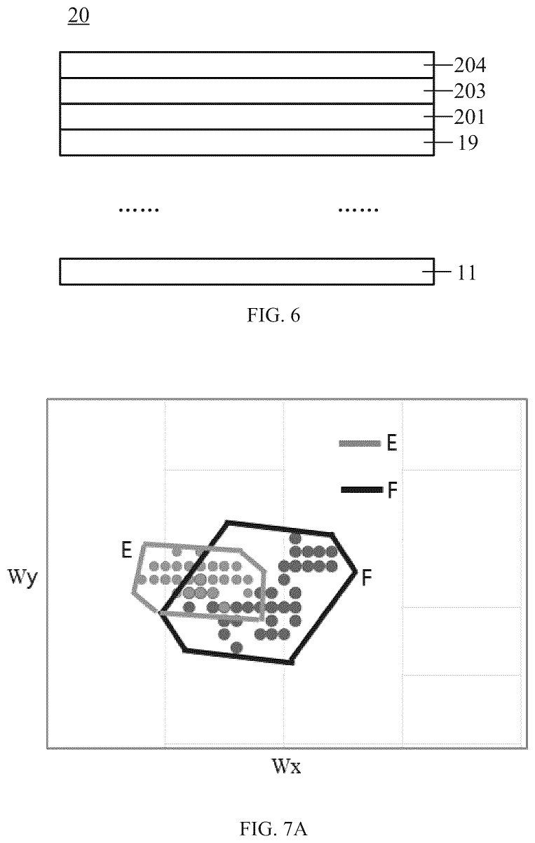

FIG. 6 is a schematic diagram of an encapsulation layer according to another embodiment of the present disclosure.

As shown in FIG. 6, the encapsulation layer 20 may include: the first inorganic layer 201 on the side of the protective layer 19 away from the base substrate 11; the organic layer 203 on the side of the first inorganic layer 201 away from the base substrate 11; and the second inorganic layer 204 on the side of the organic layer 203 away from the base substrate 11. The sign “ . . . ” in FIG. 6 may represent an omitted film layer structure between the base substrate 11 and the protective layer 19.

According to an embodiment of the present disclosure, in the case where the encapsulation layer 20 includes the first inorganic layer 201, the organic layer 203 and the second inorganic layer 204, an improvement is made to the optical extraction layer 18 so that characteristics of the second electrode 17, the optical extraction layer 18 and the protective layer 19 have the relationship represented by equation (12). Specifically, the refractive index n₁ of the material of the second electrode 17, the thickness L₁ of the second electrode 17, the refractive index n₃ of the material of the optical extraction layer 18, the thickness L₃ of the optical extraction layer 18, the refractive index n₄ of the material of the protective layer 19 and the thickness L₄ of the protective layer 19 may have a relationship represented by equation (12):

$$( {n}_{1} {L}_{1} + {n}_{3} {L}_{3} + {n}_{4} {L}_{4} ) / ( {L}_{1} + {L}_{3} + {L}_{4} ) = K \qquad ( 12 )$$

Here, K may be 1.5.

A product of a refractive index and a film thickness of a film layer is set to an effective thickness Leff. In this embodiment, a product n₃·L₃ of the refractive index n₃ of the material of the optical extraction layer 18 and the thickness L₃ of the optical extraction layer 18 may be in a range of 90 to 120, and the refractive index n₃ of the material of the optical extraction layer meets n₃>1.7. The material of the optical extraction layer 18 may be an organic material with a high refractive or an inorganic material. A refractive index of the optical extraction layer for a short wavelength 18 is higher than a refractive index of the optical extraction layer for a long wavelength, so that the sensitivity of the optical extraction layer 18 to blue light may be relatively high.

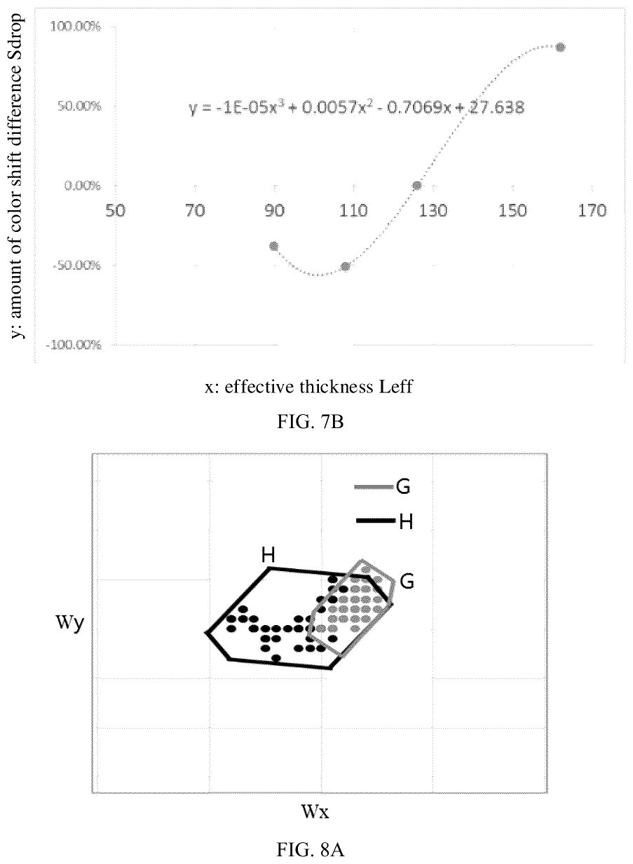

FIG. 7A is a schematic diagram showing reduction of color shift difference in a case of the encapsulation layer shown in FIG. 6 according to an embodiment of the present disclosure.

As shown in FIG. 7A, the maximum color gamut coverage of CIE1931 is 100% of NTSC. The points in box E represent the measured data of pixels in the display substrate at a same viewing angle. The border of box E is a boundary fitted for matching of experimental results, and pixels within box E may be blue pixels. Box F may serve as reference data for domain box E under the same experimental conditions. The smaller an area of box E, the smaller the color difference, indicating that the color shift difference may be reduced. To determine the extent of the color shift difference reduction, the area of box E which may be used as Ssplit and the area of box F which may be used as Sref. may be substituted into equation (3) to obtain a result of the color shift difference reduction Sdrop. In this embodiment, the effective thickness Leff may be 108, and the Sdrop obtained is −54.8%.

FIG. 7B is a diagram showing a relationship between an effective thickness and an amount of color shift difference in a case of the encapsulation layer shown in FIG. 6 according to an embodiment of the present disclosure.

As shown in FIG. 7B, the horizontal axis may represent the effective thickness (Leff), and the vertical axis may represent the amount of color shift difference (Sdrop). The relationship between the effective thickness and Sdrop may be represented by equation (13).

$$Sdrop = - 1 E - 05 {( Leff )}^{3} + 0.0057 {( Leff )}^{2} + 0.7069 ( Leff ) + 27.64 \qquad ( 13 )$$

Referring to FIG. 7, the optical extraction layer 18 for color shift difference reduction is required to meet 90<Leff<120 and n₃>1.7.

In this embodiment, the peak position in the spectrum of the first sub light-emitting layer may be in a range of 623 nm to 646 nm, the peak position in the spectrum of the second sub light-emitting layer may be in a range of 520 nm to 535 nm, and the peak position in the spectrum of the third sub light-emitting layer may be in a range of 450 nm to 465 nm.

Referring to FIG. 2, unlike the foregoing embodiments, the second insertion layer 202 may serve as the color shift adjustment layer and the color shift difference of the display substrate may be reduced by only adjusting the refractive index and thickness of the second insertion layer 202.

According to an embodiment of the present disclosure, preferably, an inorganic film layer, such as SiN and SiON, is selected as the material of the second insertion layer 202. The refractive index n₂ of the second insertion layer 202 may be in a range of 1.5 to 1.8. Since a refractive index of a film layer in the encapsulation film layer for adjusting light output is relatively low, the color shift difference adjustment for RGB at large angles may have a convergent effect.

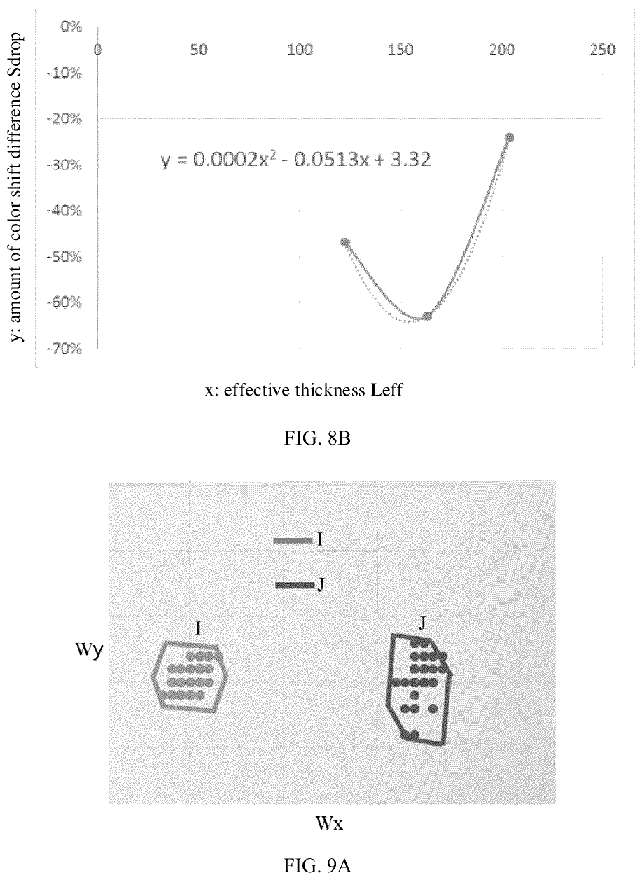

FIG. 8A is a schematic diagram showing reduction of color shift difference in a case of only adjusting a second insertion layer according to an embodiment of the present disclosure. FIG. 8B is a diagram showing a relationship between an effective thickness and an amount of color shift difference in a case of only adjusting a second insertion layer according to an embodiment of the present disclosure.

As shown in FIG. 8A, the points in box G represent measured data of pixels in the display substrate at a same viewing angle. The border of box G is a boundary fitted for matching of experimental results, and pixels in box G may be blue pixels. Box H may serve as reference data for domain box G under the same experimental conditions. The smaller an area of box G, the smaller the color difference, indicating that the color shift difference may be reduced. To determine the extent of the color shift difference reduction, the area of box G which may be used as Ssplit and the area of box H which may be used as Sref. may be substituted into equation (3) to obtain a color shift difference reduction result Sdrop. In this embodiment, the effective thickness Leff may be 163, and the Sdrop obtained is −63%.

As shown in FIG. 8B, the horizontal axis may represent the effective thickness (Leff), and the vertical axis may represent the amount of color shift difference (Sdrop). The relationship between the effective thickness and Sdrop may be represented by equation (14).

$$Sdrop = 0.0002 {( Leff )}^{2} + 0.0513 ( Leff ) + 3.32 \qquad ( 14 )$$

With continued reference to FIG. 8B, the second insertion layer 202 for color shift difference reduction is required to meet 130<Leff<190. That is, a product n₂·L₂ of the refractive index n₂ of the material of the second insertion layer 202 and the thickness L₂ of the second insertion layer 202 may be in a range of 130 to 190, and the refractive index n₂ of the material of the second insertion layer may be in a range of 1.5 to 1.8.

In this embodiment, the peak position in the spectrum of the first sub light-emitting layer may be in a range of 615 nm to 635 nm, the peak position in the spectrum of the second sub light-emitting layer may be in a range of 515 nm to 535 nm, and the peak position in the spectrum of the third sub light-emitting layer may be in a range of 450 nm to 460 nm.

Referring to FIG. 6, unlike the foregoing embodiments, the protective layer 19 may serve as the color shift adjustment layer and the color shift difference of the display substrate may be reduced by only adjusting the refractive index and thickness of the protective layer 19.

According to an embodiment of the present disclosure, the protective layer 19 may serve as a film layer with a low refractive index. Since the protective layer 19 is close to the second electrode 17, it may have a more direct impact on the characteristics of the microcavity, so that the color shift difference at a large angle may be effectively adjusted.

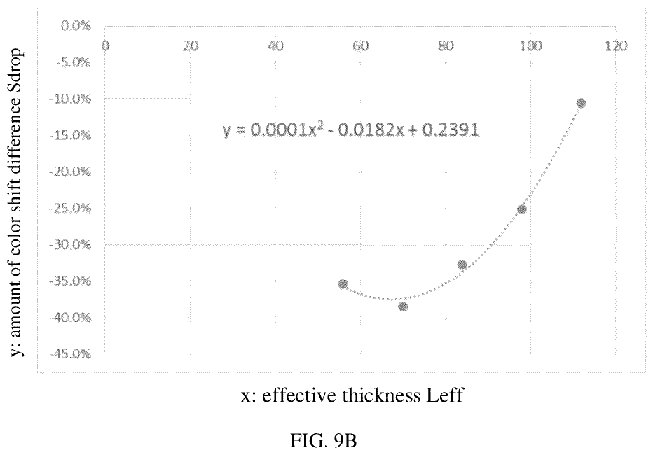

FIG. 9A is a schematic diagram showing reduction of color shift difference in a case of only adjusting a protective layer according to an embodiment of the present disclosure. FIG. 9B is a diagram showing a relationship between an effective thickness and an amount of color shift difference in a case of only adjusting a protective layer according to an embodiment of the present disclosure.

As shown in FIG. 9A, the points in box I represent the measured data of pixels in the display substrate at a same viewing angle. The border of box I is a boundary fitted for the matching of experimental results, and pixels in box I may be blue pixels. Box J may serve as reference data for domain box I under the same experimental conditions. The smaller an area of box I, the smaller the color difference, indicating that the color shift difference may be reduced. To determine the extent of the reduction of color shift difference, the area of box I which may be used as Ssplit and the area of box J which may be used as Sref. may be substituted into equation (3) to obtain a result of the color shift difference reduction Sdrop. In this embodiment, the effective thickness Leff at this time may be 70, and Sdrop is reduced by 38.5% with respect to Sref.

As shown in FIG. 9B, the horizontal axis may represent the effective thickness (Leff), and the vertical axis may represent the amount of color shift difference (Sdrop). The relationship between the effective thickness and Sdrop may be represented by equation (15).

$$Sdrop = 0.0001 {( Leff )}^{2} - 0.0182 ( Leff ) + 0.2391 \qquad ( 15 )$$

With continued reference to FIG. 9B, the protective layer 19 for color shift difference reduction is required to meet 56<Leff<84. That is, a product n₄·L₄ of the refractive index n₄ of the material of the protective layer 19 and the thickness La of the protective layer 19 may be in a range of 56 to 84, and the refractive index n₄ of the material of the protective layer 19 may be in a range of 1.4 to 1.5. When combining this with a fixed range of Leff of the second electrode 17 between 1.28 and 1.92, the optimal color shift difference reduction effect may be achieved by fixing the range of Leff of the second electrode 17 between 1.28 and 1.92, that is, the product n₁·L₁ of the refractive index n₁ of the material of the second electrode 17 and the thickness L₁ of the second electrode 17 is set in a range of 1.28 to 1.92.

In this embodiment, the peak position in the spectrum of the first sub light-emitting layer may be in a range of 620 nm to 635 nm, the peak position in the spectrum of the second sub light-emitting layer may be in a range of 510 nm to 530 nm, and the peak position in the spectrum of the third sub light-emitting layer may be in a range of 445 nm to 465 nm.

The embodiments provided in the present disclosure may be applicable to structures such as OLED film layer structures (including film layers in the microcavity being increased or decreased, a plurality of light-emitting stack structures, etc.), multi-layer encapsulation structures, COE devices, EES devices, and QLEDs (Quantum Dot Light Emitting Diodes). The differences in film layer materials are only differences with respect to the reference data, but do not affect the fluctuation in the film thickness by using a same process level, as well as a change rule of the film layer.

According to the embodiments of the present disclosure, the color shift difference reduction may be achieved by adjusting the thickness and refractive index of the film layer in the display substrate, so as to reduce the probability of distribution being off specification caused by multi-point color shift differences on the display screen, so that an overall display effect and yield of the display substrate may be improved.

An embodiment of the present disclosure further provides a display device, which may include the display substrate described in any of the above embodiments. The display device may be any product or component with display function, such as a mobile phone, tablet, TV, monitor, laptop, digital photo frame, navigation device, etc.

It will be understood that the display device provided in the embodiments of the present disclosure includes the above-mentioned display substrate. The beneficial effects of the display device are the same as those of the above-mentioned display substrate, which will not be repeated here.

Although some embodiments of the overall concept of the present disclosure have been illustrated and described, those skilled in the art will understand that changes may be made to these embodiments without departing from the principles and spirit of the overall invention concept of the present disclosure. The scope of the present disclosure is defined by the claims and their equivalents.

1. A display substrate, comprising:
a base substrate;
a first electrode on the base substrate;
a first light-emitting layer on a side of the first electrode away from the base substrate;
a first hole blocking layer on a side of the first light-emitting layer away from the base substrate;
a first electron transport layer on a side of the first hole blocking layer away from the base substrate;
an electron injection layer on a side of the first electron transport layer away from the base substrate;
a second electrode on a side of the electron injection layer away from the base substrate;
an optical extraction layer on a side of the second electrode away from the base substrate;
a protective layer on a side of the optical extraction layer away from the base substrate; and
an encapsulation layer on a side of the protective layer away from the base substrate,
wherein a refractive index of a material of the optical extraction layer is greater than a refractive index of a material of the protective layer, and the refractive index of the material of the protective layer is greater than a refractive index of a material of the second electrode.

2. The display substrate according to claim 1, wherein the display substrate comprises a color shift adjustment layer, the color shift adjustment layer is selected from at least one of the optical extraction layer, the protective layer, or the encapsulation layer, and the color shift adjustment layer and the second electrode meet:
$$\sum ( {n}_{i} {L}_{i} ) / \sum {L}_{i} = K ,$$
wherein n represents a refractive index of a material of each layer, L represents a thickness of each layer, i is a positive integer, and K is greater than 1.

3. The display substrate according to claim 2, wherein the encapsulation layer comprises:
a first inorganic layer on the side of the protective layer away from the base substrate;
a second insertion layer on a side of the first inorganic layer away from the base substrate;
an organic layer on a side of the second insertion layer away from the base substrate; and
a second inorganic layer on a side of the organic layer away from the base substrate.

4. The display substrate according to claim 3, wherein the refractive index n₁ of the material of the second electrode, a thickness L₁ of the second electrode, a refractive index n₂ of a material of the second insertion layer and a thickness L₂ of the second insertion layer meet:
$$( {n}_{1} {L}_{1} + {n}_{2} {L}_{2} ) / ( {L}_{1} + {L}_{2} ) = K ,$$
wherein K is in a range of 1.3 to 1.6.

5. The display substrate according to claim 4, wherein the refractive index n₁ of the material of the second electrode and the refractive index n₂ of the material of the second insertion layer meets |n₁−n₂|>1.

6. The display substrate according to claim 2, wherein the encapsulation layer comprises:
a first insertion layer on the side of the protective layer away from the base substrate;
a first inorganic layer on a side of the first insertion layer away from the base substrate;
an organic layer on a side of the first inorganic layer away from the base substrate; and
a second inorganic layer on a side of the organic layer away from the base substrate.

7. The display substrate according to claim 6, wherein the refractive index n₁ of the material of the second electrode, a thickness L₁ of the second electrode, the refractive index n₃ of the material of the optical extraction layer, a thickness L₃ of the optical extraction layer, the refractive index n₄ of the material of the protective layer, a thickness L₄ of the protective layer, a refractive index n₅ of a material of the first insertion layer and a thickness L₅ of the first insertion layer meet:
$$( {n}_{1} {L}_{1} + {n}_{3} {L}_{3} + {n}_{4} {L}_{4} + {n}_{5} {L}_{5} ) / ( {L}_{1} + {L}_{3} + {L}_{4} + {L}_{5} ) = K ,$$
wherein K is in a range of 1.5 to 2.0.

8. The display substrate according to claim 7, wherein the refractive index n₁ of the material of the second electrode and the refractive index n₃ of the material of the optical extraction layer meets |n₁−n₃|>1.

9. The display substrate according to claim 7, wherein the refractive index n₄ of the material of the protective layer and the refractive index n₃ of the material of the optical extraction layer meets |n₄−n₃|>0.3.

10. The display substrate according to claim 7, wherein the refractive index n₅ of the material of the first insertion layer and the refractive index n₄ of the material of the protective layer meets |n₅−n₄|>0.2.

11. The display substrate according to claim 2, wherein the encapsulation layer comprises:
a first inorganic layer on the side of the protective layer away from the base substrate;
an organic layer on a side of the first inorganic layer away from the base substrate; and
a second inorganic layer on a side of the organic layer away from the base substrate.

12. The display substrate according to claim 11, wherein the refractive index n₁ of the material of the second electrode, a thickness L₁ of the second electrode, the refractive index n₃ of the material of the optical extraction layer, a thickness L₃ of the optical extraction layer, the refractive index n₄ of the material of the protective layer and a thickness L₄ of the protective layer meet:
$$( {n}_{1} {L}_{1} + {n}_{3} {L}_{3} + {n}_{4} {L}_{4} ) / ( {L}_{1} + {L}_{3} + {L}_{4} ) = K ,$$
wherein K is 1.5.

13. The display substrate according to claim 11, wherein a product n₃·L₃ of the refractive index n₃ of the material of the optical extraction layer and a thickness L₃ of the optical extraction layer is in a range of 90 to 120.

14. The display substrate according to claim 11, wherein the refractive index n₃ of the material of the optical extraction layer meets n₃>1.7.

15. The display substrate according to claim 3, wherein a product n₂·L₂ of a refractive index n₂ of a material of the second insertion layer and a thickness L₂ of the second insertion layer is in a range of 130 to 190.

16. The display substrate according to claim 15, wherein the refractive index n₂ of the material of the second insertion layer meets 1.5<n₂<1.8.

17. The display substrate according to claim 11, wherein a product n₄·L₄ of the refractive index n₄ of the material of the protective layer and a thickness L₄ of the protective layer is in a range of 56 to 84;
wherein the refractive index n4 of the material of the protective layer meets 1.4<n4<1.5; and
wherein a product n1·L1 of the refractive index n1 of the material of the second electrode and a thickness L1 of the second electrode is in a range of 1.28 to 1.92.

18-19. (canceled)

20. The display substrate according to claim 1, further comprising:
a hole injection layer on the side of the first electrode away from the base substrate;
a first hole transport layer on a side of the hole injection layer away from the base substrate;
a second light-emitting layer on a side of the first hole transport layer away from the base substrate;
a second hole blocking layer on a side of the second light-emitting layer away from the base substrate;
a second electron transport layer on a side of the second hole blocking layer away from the base substrate;
a charge generation layer on a side of the second electron transport layer away from the base substrate; and
a second hole transport layer on a side of the charge generation layer away from the base substrate, wherein the first light-emitting layer is on a side of the second hole transport layer away from the base substrate.

21. The display substrate according to claim 1,
wherein a material of the first electrode comprises at least one of silver, indium tin oxide/silver/indium tin oxide, or a nickel chromium alloy;
wherein the material of the second electrode comprises at least one of a transparent conductive oxide, a magnesium silver alloy, aluminum, magnesium, or
silver;
wherein Sdrop≤0, and Sdrop is obtained through a following equation:
Sdrop=((Ssplit−Sref.)/Sref.)*100%, and
wherein Ssplit is an area of an enclosed color gamut of the display substrate in a color space, Sref, is an area of an enclosed color gamut of a reference display substrate in the color space, and Sdrop is a variation of split S with respect to Sref.

22. (canceled)

23. A display device, comprising the display substrate according to claim 1.
